(19) United States
(12) Patent Application Publication
(10) Pub. No.: US 2008/0029809 A1
(43) Pub. Date: Feb. 7, 2008

(54) Semiconductor device having a vertical transistor structure

(76) Inventors: Jun Morioka, Kitakyushu-shi (JP); Shinichi Taka, Yokohama-shi (JP); Kiminori Watanabe, Kawasaki-shi (JP); Koji Yonemura, Kitakyushu-shi (JP); Chihiro Yoshino, Yokkaichi-shi (JP); Keita Takahashi, Kitakyushu-shi (JP)

Correspondence Address: SPRINKLE IP LAW GROUP, 1301 W. 25TH STREET, SUITE 408, AUSTIN, TX, 78705, US

(21) Appl. No.: 11/890,068

(22) Filed: Aug. 3, 2007

(30) Foreign Application Priority Data
Aug. 4, 2006 (JP) 2006-213571

(51) Int. Cl. H01L 29/78; H01L 27/082

(52) U.S. Cl. 257/329; 257/593; 257/E29.198; 257/E29.262

(57) ABSTRACT

A semiconductor device includes a semiconductor substrate having a semiconductor layer on a major surface thereof. The semiconductor layer is formed to extend in the vertical direction of the major surface of the semiconductor substrate. A stress application layer is provided on either side of the semiconductor layer and applies a stress to the semiconductor layer.

### CROSS-REFERENCE TO RELATED APPLICATIONS

This application is based upon and claims the benefit of priority from prior Japanese Patent Application No. 2006-213571, filed Aug. 4, 2006, the entire contents of which are incorporated herein by reference.

### BACKGROUND OF THE INVENTION

1. Field of the Invention

The present invention relates to a semiconductor device having a vertical transistor structure. More specifically, the invention relates to a vertical high-speed bipolar transistor and a vertical high-withstanding low-resistance field-effect transistor.

2. Description of the Related Art

In general, the high-speed performance factor of a bipolar transistor is expressed by cutoff frequency (f_{T}). For high-speed and low-power consumption, high f_{T} characteristics are required with smaller collector current (I_{c}). The f_{T} characteristics of a bipolar transistor depend on the transit time of electrons (carriers) that pass a base region and a collector region and the charging/discharging time constant of each of an emitter/base junction and a collector/base junction. The transit time of electrons in the base region is a dominant factor for improving the f_{T} characteristics. In place of conventional ion implantation, therefore, a technique of reducing the width of a base region using epitaxial growth in a base forming process has been tried.

The f_{T} characteristics of a bipolar transistor are influenced by a shallow junction of an impurity diffusion layer serving as an emitter region, a base region and a collector region as the transistor decreases in area. Moreover, the SiGe-HBT (Heterojunction Bipolar Transistor) technique has improved the f_{T} characteristics of the bipolar transistor. This technique employs a drift field acceleration effect in a base region, which generates a voltage gradient (electric field) in the base region by adding germanium unevenly.

However, though a further improvement of f_{T} characteristics of a bipolar transistor requires a more reduction of base width or that of base concentration, it causes a problem of increasing base resistance (RB) and decreasing a withstanding voltage (BVceo) as tradeoff characteristics.

In a prior art horizontal high-withstanding low-resistance field-effect transistor (N-channel type in particular), the resistance of an N-type drift layer is a factor to determine the resistance of the transistor. The withstanding voltage of the transistor depends on a depletion layer extending from a P layer. In this prior art transistor, the concentration of the N-type drift layer needs to increase in order to achieve a high withstanding voltage, whereas it needs to decrease in order to achieve a low resistance.

In the horizontal high-withstanding low-resistance field effect transistor, it is effective to expand the drift layer in order to improve the performance (high withstanding voltage and low resistance). If, however, the drift layer is simply expanded, the transistor will increase in resistance.

The high-speed bipolar transistor and high-withstanding low-resistance field effect transistor have already been well known (for example, see T. Sugano (supervisor) and Y. Nagata (editor), “Very High Speed Digital Device, Series I, Very High Speed Bipolar Device,” Baifukan Co., Ltd.; G. L. Patton, J. H. comfort, B. S. Meyerson, E. Crabbe, G. Scilla, E. DeFresart, J. M. C. Stork, J. Y.-C. Sun, D. L. Harame, and J. N. Burghartz, “7G5-GHz f_{T} SiGe-base Heterojunction Bipolar Transistors,” IEEE Electron Device Lett., Vol. 11, pp 171-173, April 1990; “Power Device Power IC Handbook,” Research Committee of High-Performance Multi-Function Power Device Power IC in the Institute of electrical Engineering of Japan, Corona Publishing Co., Ltd.; Chin-Yu Tsai, Taylor Efland, Sameer Pendharkar, Hozef Mitros, Alison Tessmer, Jeff Smith, John Erdeljac, and Lou Hutter, “16-60V Rated LDMOS Show Advanced Performance in an 0.72 μm Evolution BiCMOS Power Technology,” Mixed Signal Power Component and Power BiCMOS process Development Texas Instruments Incorporated 1997 IEEE; and V. Parthasarathy, R. Zhu, W. Peterson, M. Zunhino and R. Baird, “A 33V, 0.25 mΩ-cm² n-channel LDMOS in a 0.65 μm Smart Power Technology for 20-30V Applications,” Transportation Silicon Technology center, Motorola SPS Proceedings of 1998 International Symposium on Power Semiconductor Device & ICs).

### BRIEF SUMMARY OF THE INVENTION

According to a first aspect of the present invention, there is provided a semiconductor device comprising:

a semiconductor substrate having a semiconductor layer on a major surface thereof, the semiconductor layer being formed to extend in a vertical direction of the major surface; and

a stress application layer provided on either side of the semiconductor layer, the stress application layer applying a stress to the semiconductor layer.

According to a second aspect of the present invention, there is provided a semiconductor device comprising:

a semiconductor substrate having a semiconductor layer on a major surface thereof, the semiconductor layer being formed to extend in a vertical direction of the major surface;

a collector layer and a base layer both formed in the semiconductor layer;

a first stress application layer formed on either side of the collector layer of the semiconductor layer to apply a stress to the collector layer;

a second stress application layer formed on either side of the base layer of the semiconductor layer to apply a stress to the base layer;

a base electrode connected to the base layer;

an emitter layer provided on the semiconductor layer; and

an emitter electrode connected to the emitter layer.

According to a third aspect of the present invention, there is provided a semiconductor device comprising:

a semiconductor substrate having a semiconductor layer on a major surface thereof, the semiconductor layer being formed to extend in a vertical direction of the major surface;

a drain layer formed in the semiconductor layer;

a stress application layer provided on either side of the drain layer of the semiconductor layer, the stress application layer applying a stress to the drain layer;

a channel region provided on the semiconductor layer;

a gate electrode provided close to the channel region;

a source layer provided in the channel region; and

a source electrode connected to the source layer.

### BRIEF DESCRIPTION OF THE SEVERAL VIEWS OF THE DRAWING

FIG. 1A is a plan view showing a basic configuration of a semiconductor device according to a first embodiment of the present invention;

FIG. 1B is a sectional view of the semiconductor device shown in FIG. 1A;

FIG. 2 is a diagram of computation results of theoretical values of mobility improvement rate of electrons and holes in silicon deposited on SiGe;

FIG. 3 is a sectional view showing a configuration of a semiconductor device (high-speed bipolar transistor) according to a second embodiment of the present invention;

FIG. 4 is a sectional view of the semiconductor device according to the second embodiment of the present invention, illustrating a step of manufacturing the semiconductor device;

FIG. 5 is a sectional view of the semiconductor device according to the second embodiment of the present invention, illustrating a step of manufacturing the semiconductor device;

FIG. 6 is a sectional view of the semiconductor device according to the second embodiment of the present invention, illustrating a step of manufacturing the semiconductor device;

FIG. 7 is a sectional view of the semiconductor device according to the second embodiment of the present invention, illustrating a step of manufacturing the semiconductor device;

FIG. 8 is a sectional view of the semiconductor device according to the second embodiment of the present invention, illustrating a step of manufacturing the semiconductor device;

FIG. 9 is a sectional view of the semiconductor device according to the second embodiment of the present invention, illustrating a step of manufacturing the semiconductor device;

FIG. 10 is a sectional view of the semiconductor device according to the second embodiment of the present invention, illustrating a step of manufacturing the semiconductor device;

FIG. 11 is a sectional view of the semiconductor device according to the second embodiment of the present invention, illustrating a step of manufacturing the semiconductor device;

FIG. 12 is a sectional view of the semiconductor device according to the second embodiment of the present invention, illustrating a step of manufacturing the semiconductor device;

FIG. 13 is a sectional view of the semiconductor device according to the second embodiment of the present invention, illustrating a step of manufacturing the semiconductor device;

FIG. 14 is a sectional view of the semiconductor device according to the second embodiment of the present invention, illustrating a step of manufacturing the semiconductor device;

FIG. 15 is a sectional view of the semiconductor device according to the second embodiment of the present invention, illustrating a step of manufacturing the semiconductor device;

FIG. 16 is a sectional view of the semiconductor device according to the second embodiment of the present invention, illustrating a step of manufacturing the semiconductor device;

FIG. 17 is a sectional view showing a configuration of a semiconductor device (high-speed bipolar transistor) according to a third embodiment of the present invention;

FIG. 18 is a sectional view of the semiconductor device according to the third embodiment of the present invention, illustrating a step of manufacturing the semiconductor device;

FIG. 19 is a sectional view of the semiconductor device according to the third embodiment of the present invention, illustrating a step of manufacturing the semiconductor device;

FIG. 20 is a sectional view of the semiconductor device according to the third embodiment of the present invention, illustrating a step of manufacturing the semiconductor device;

FIG. 21 is a sectional view of the semiconductor device according to the third embodiment of the present invention, illustrating a step of manufacturing the semiconductor device;

FIG. 22 is a sectional view of the semiconductor device according to the third embodiment of the present invention, illustrating a step of manufacturing the semiconductor device;

FIG. 23 is a sectional view of the semiconductor device according to the third embodiment of the present invention, illustrating a step of manufacturing the semiconductor device;

FIG. 24 is a sectional view of the semiconductor device according to the third embodiment of the present invention, illustrating a step of manufacturing the semiconductor device;

FIG. 25 is a sectional view of the semiconductor device according to the third embodiment of the present invention, illustrating a step of manufacturing the semiconductor device;

FIG. 26 is a sectional view of the semiconductor device according to the third embodiment of the present invention, illustrating a step of manufacturing the semiconductor device;

FIG. 27 is a sectional view of the semiconductor device according to the third embodiment of the present invention, illustrating a step of manufacturing the semiconductor device; and

FIG. 28 is a sectional view of the semiconductor device according to the third embodiment of the present invention, illustrating a step of manufacturing the semiconductor device.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of dimensions. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### FIRST EMBODIMENT

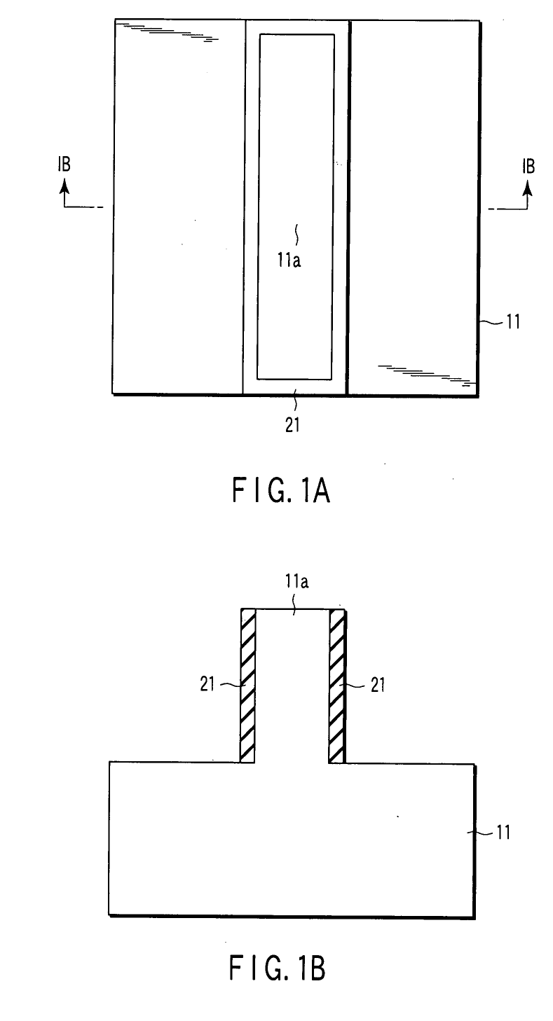

FIGS. 1A and 1B show a basic configuration of a semiconductor device according to a first embodiment of the present invention. FIG. 1A is a plan view of the semiconductor device and FIG. 1B is a sectional view taken along line IB-IB of FIG. 1A.

A plate-shaped (or a bar-shaped) semiconductor layer (referred to as a Si post) 11a is formed on the major surface of a semiconductor substrate (e.g., Si substrate) 11 upright in the vertical direction of the substrate 11. A stress applying layer 21 is provided on either side (outer region) to apply a tensile stress (distortion stress) in the vertical direction perpendicular to the major surface of the Si substrate 11. For example, an insulating silicon nitride (SiN) film is used as the stress applying layer 21, as is a laminated film of an insulative silicon nitride film and a silicon oxide (SiO₂) film, a conductive silicon germanium (SiGe) mixed-crystal film that is formed by substituting germanium for part of silicon.

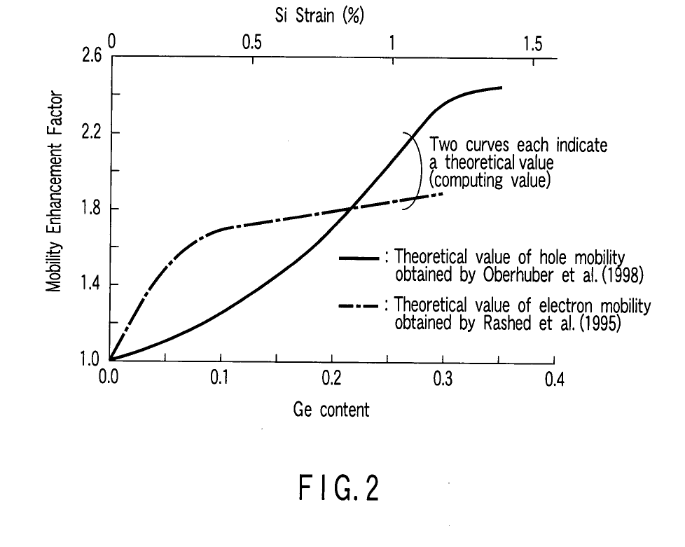

FIG. 2 shows computation results of theoretical figure of mobility of electrons and holes. More specifically, it shows a strain (%) of silicon and a mobility improvement rate of electrons and holes when the silicon is deposited on SiGe. As is apparent from FIG. 2, as the concentration of Ge increases, the strain of silicon increases and so does the carrier mobility (indicated by a one-dot-one-dash line).

Assume that in the structure shown in FIGS. 1A and 1B, the stress application layer 21 applies a tensile stress to the silicon substrate 11 in the vertical direction of the substrate to strain the silicon post 11a about 1%. In this case, the carrier mobility on either side of the silicon post 11a improves about 80%. It is thus expected that cutoff frequency f_{T} will be improved about 60%. If, therefore, a bipolar transistor or a field-effect transistor (FET) having such a structure is actually formed, its performance can greatly be improved.

A high-speed bipolar transistor and a withstanding low-resistance field-effect transistor to which the semiconductor device shown in FIGS. 1A and 1B is applied will be described below.

### SECOND EMBODIMENT

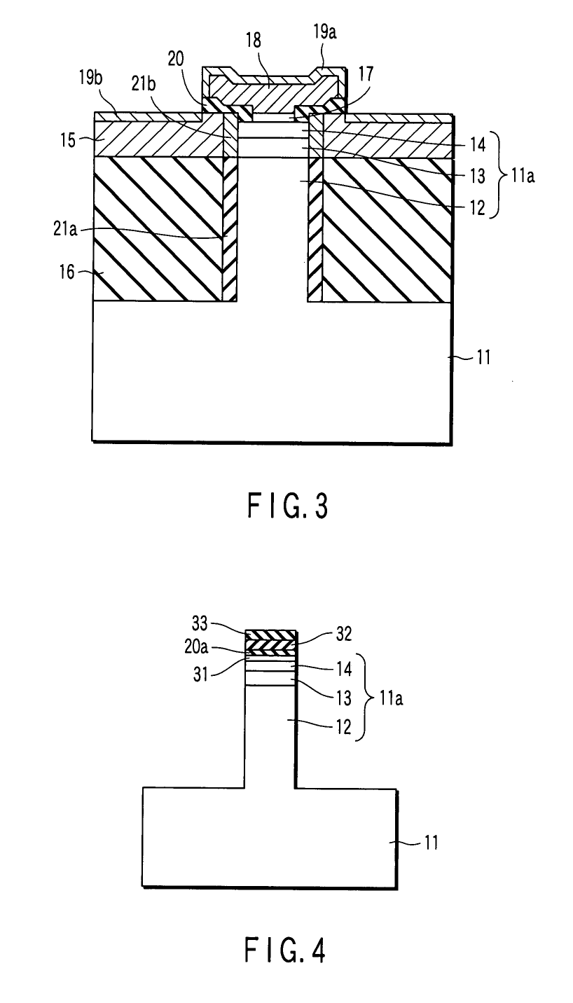

FIG. 3 shows a configuration of a semiconductor device according to a second embodiment of the present invention. In the second embodiment, the semiconductor device will be described taking a vertical high-speed bipolar transistor. The same components as those of the semiconductor device shown in FIGS. 1A and 1B are denoted by the same reference numerals and their detailed descriptions are omitted.

A plate-shaped (or bar-shaped) silicon post 11a is formed on the major surface of a silicon substrate 11. The silicon post 11a includes a collector layer (epitaxial layer) 12, a buffer layer (silicon layer) 13 and a base layer (SiGe layer) 14 in advance.

A first stress application layer 21a is formed on at least either side of the collector layer 12 to apply a tensile stress to either side of the collector layer 12 in the vertical direction. A second stress application layer 21b is formed on either side of each of the buffer layer 13 and base layer 14 to apply a tensile stress to either side of each of the layers 13 and 14 (at least the base layer 14) in the vertical direction. As the first stress application layer 21a, for example, an insulative SiN film (nitride film) or a laminated film of a SiN film and a SiO₂ film is used. As the second stress application layer 21b, for example, a conductive SiGe film is used. The second stress application layer 21b applies a tensile stress to the base layer 14 and also serves as an extraction electrode for electrically connecting the base 14 to a base polysilicon electrode 15.

An insulation film 16 is provided on the major surface of the silicon substrate 11 and either side of the first stress application layer 21a. The base polysilicon electrode 15 is provided on the insulation film 16 and either side of the second stress application layer 21b.

An emitter (diffusion) layer 17 using polysilicon and an emitter polysilicon electrode 18 are provided on the surface of the silicon post 11a. Silicide layers 19a and 19b for low resistance are provided in the surface areas of the emitter polysilicon electrode 18 and base polysilicon electrode 15, respectively, when the need arises.

The emitter polysilicon electrode 18 and silicide layer 19a are insulated from the base polysilicon electrode 15, second stress application layer 21b and base layer 14 by an insulation film 20.

With the vertical high-speed bipolar transistor so configured, the carriers (electrons) injected from the emitter layer 17 can be improved in mobility in both the collector layer 12 and base layer 14, and the f_{T} characteristics can be improved. In other words, if a tensile stress is locally applied to the silicon post 11a (the silicon post 11a is locally strained), the f_{T} characteristics of the transistor can be improved due to an increase in carrier mobility in the base and collector layers without increasing in RB or decreasing in BVceo.

An example of a method of manufacturing the vertical high-speed bipolar transistor shown in FIG. 3 will be described in brief. In the second embodiment, a very common process is used in the example of the manufacturing method and, for example, the order of steps is not limited to the process.

Referring first to FIG. 4, an epitaxial layer serving as a collector layer 12, a silicon layer serving as a buffer layer 13, and a SiGe layer serving as a base layer 14 are grown in sequence on a silicon substrate 11 by epitaxial growth. A cap layer (polysilicon) 31 serving as an emitter layer 17 is grown on the SiGe layer by epitaxial growth. An insulation film 20a, a nitride film (e.g., Si₃N₄ film) 32, and an insulation film 33 are formed in sequence on the cap layer 31 by chemical vapor deposition (CVD). Then, the insulation film 33, nitride film 32 and insulation film 20a are removed by selective RIE, except where a silicon post 11a is formed. After that, the major surface areas of the cap layer 31, SiGe layer, silicon layer, epitaxial layer and silicon substrate 11 are removed by selective RIE, except where the silicon post 11a is formed. Thus, the silicon post 11a is shaped like a plate (or a bar) on the major surface of the silicon substrate 11 and includes the collector layer 12, buffer layer 13 and base layer 14.

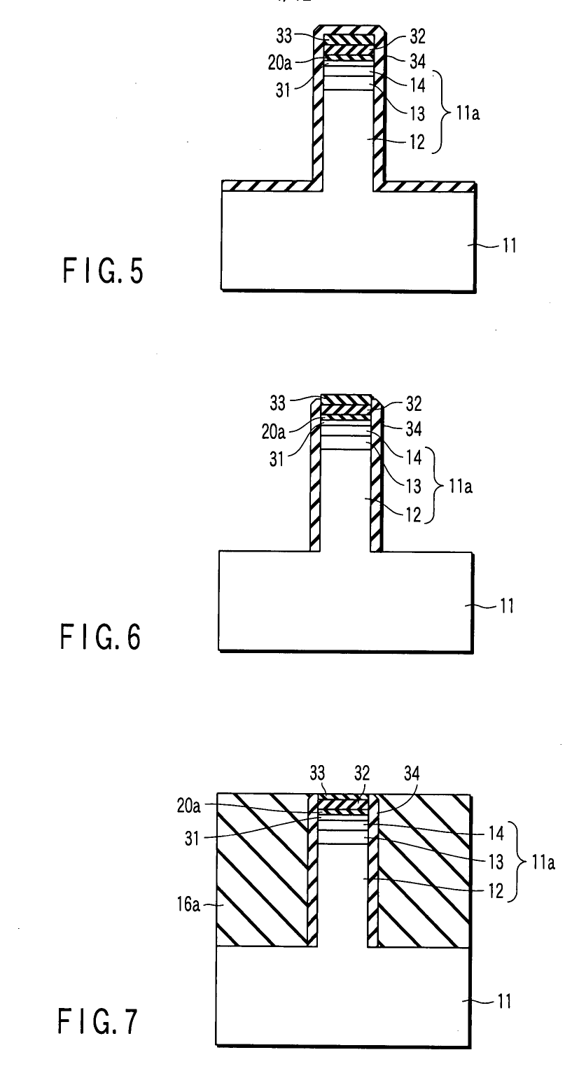

Referring then to FIG. 5, a nitride film 34, which is to serve as a first stress application layer 21a, is formed by CVD in the major surface area of the silicon substrate 11 including an outer region of the silicon post 11a.

Referring then to FIG. 6, the nitride film 34 is removed by selective RIE from the major surface of the silicon substrate 11 and from the insulation film 33. Thus, the major surface of the silicon substrate 11, the top surface of the insulation film 33, and part of either side of the insulation film are exposed.

Referring then to FIG. 7, an insulation film 16a is formed by CVD at least on the major surface of the silicon substrate 11. Then, the top surface of the insulation film 16a is flattened by chemical mechanical polishing (CMP), together with the top surface of the insulation film 33.

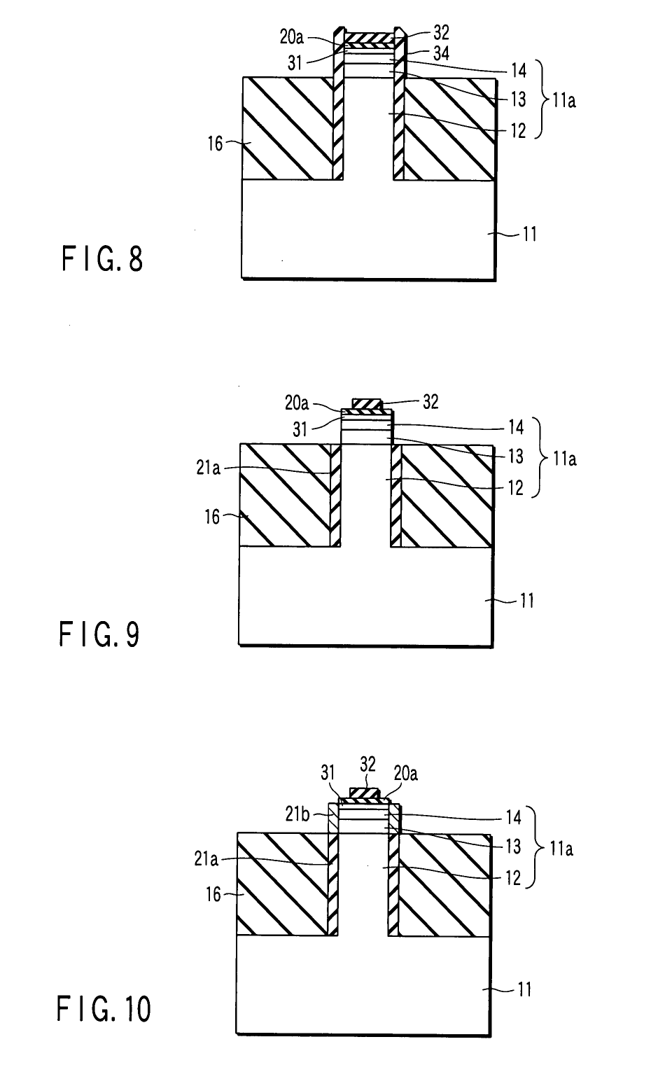

After that, the top surface of the insulation film 16a and the insulation film 33 are removed by etching. As shown in FIG. 8, the etching is performed such that the top surface of the insulation film 16a becomes almost flush with that of the collector layer 12, thereby completing the insulation film 16a.

Referring then to FIG. 9, the nitride film 34 that protrudes from the top surface of the insulation film 16 is removed by etching, and part of the nitride film 32 is removed be selective etching in order to form the emitter layer 17 described later. Thus, the first stress application layer 21a made of the nitride film 34 is completed.

Referring then to FIG. 10, a SiGe layer is grown by selective epitaxial growth on either side of the buffer layer 13, base layer 14 and cap layer 31 which are exposed by removing the nitride film 34. Thus, the second stress application layer 21b (stress source) is formed to communicate with the first stress application layer 21a.

Referring then to FIG. 11, a polysilicon film 15a is formed by CVD on the entire surface of the resultant structure including the top surface of the insulation film 16. The top of the polysilicon film 15a is flattened by CMP until the top surface of the nitride film 32 is exposed.

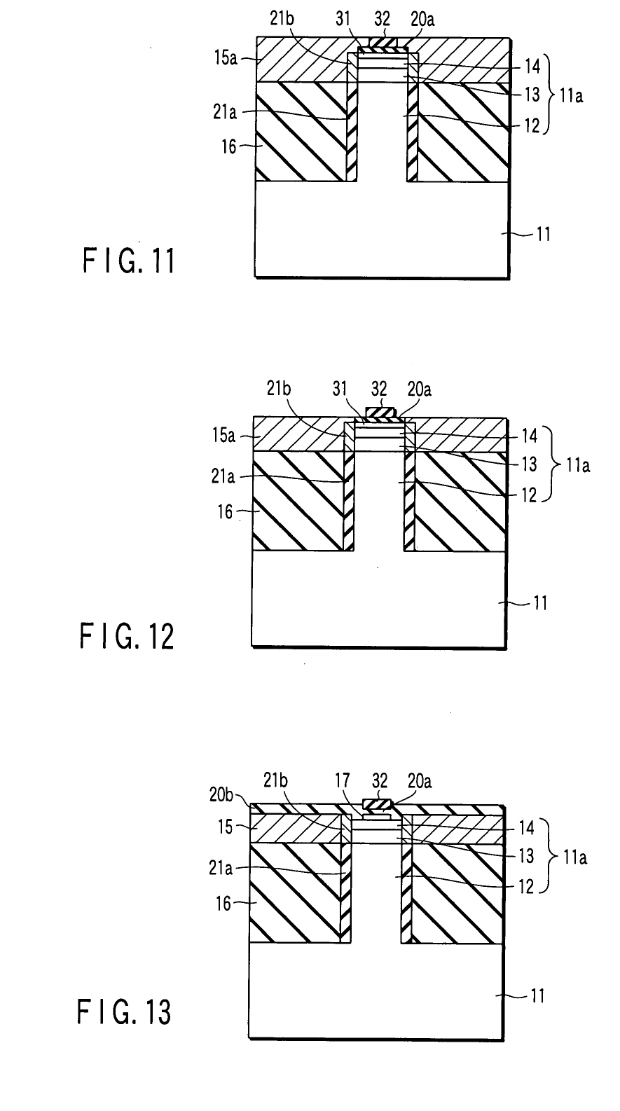

Referring then to FIG. 12, the polysilicon film 15a is etched until its top surface becomes almost flush with the top surface of the insulation film 20a.

Referring then to FIG. 13, the top surface of the polysilicon film 15a, insulation film 20a and cap layer 31 are removed again by selective etching. Since the nitride film 32 is used as a mask for the etching, an emitter layer 17 including the cap layer 31 is formed on the silicon post 11a. At the same time, the top surface of the polysilicon film 15a is removed such that it becomes flush with that of the second stress application layer 21b, thus forming a base polysilicon electrode 15 made of the polysilicon film 15a. An insulation film 20b including the top surface of each of the base polysilicon electrode 15 and second stress application layer 21b is formed by CVD to communicate with the insulation film 20a, and then the top surface of the insulation film 20b is removed by etching.

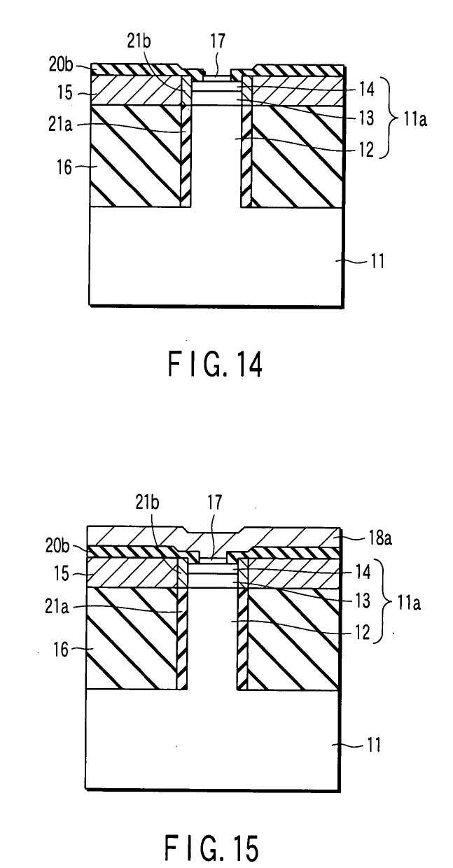

Referring then to FIG. 14, the nitride film 32 and insulation film 20a are removed by etching using resist (not shown) and then the insulation film 20b is partly removed by etching.

After the resist remaining on the insulation film 20b is removed, a polysilicon film 18a serving as an emitter polysilicon electrode 18 is formed by CVD on the emitter layer 17 and insulation film 20b, as shown in FIG. 15. Further, impurities are ion-implanted into the emitter layer 17, and rapid thermal annealing (RTA) is performed for the emitter layer 17.

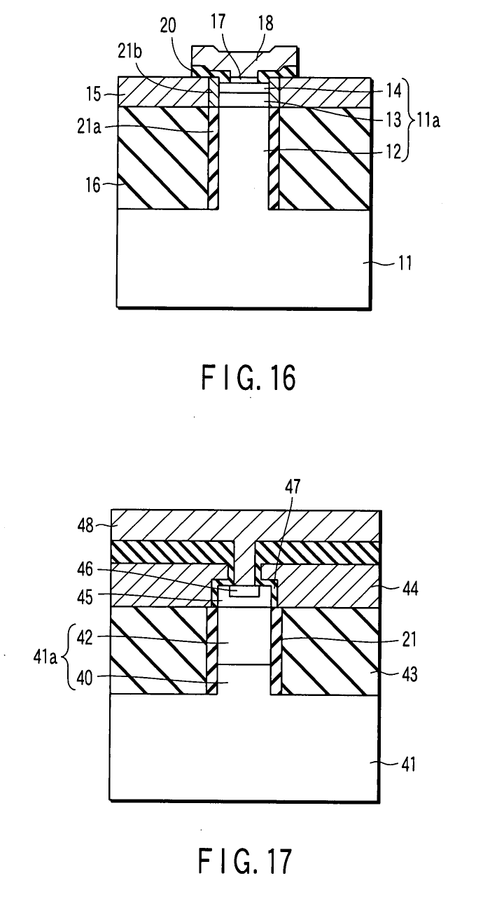

Referring then to FIG. 16, the polysilicon film 18a is treated by RIE to form an emitter polysilicon electrode 18, while the insulation film 20b is treated by RIE to form the insulation film 20. Further, impurities are ion-implanted into the base layer 14, and RTA is performed for the base layer 14.

Finally, a laminated film of, e.g., a titanium (Ti) film and a titanium nitride (TiN) film is formed on the surface of the base polysilicon electrode 15 and that of the emitter polysilicon electrode 18 by physical vapor deposition (PVD) when the need arises. Then, the laminated film is silicified into silicide layers 19a and 19b by RTA, thereby completing a vertical high-speed bipolar transistor as shown in FIG. 3.

As described above, a stress application layer for applying a tensile stress to either side of the plate-shaped or bar-shaped silicon post in the vertical direction of the silicon substrate, is provided on the major surface of the silicon substrate. In the vertical high-speed bipolar transistor having a collector layer, a buffer layer and a base layer in the vertical direction, an insulative stress application layer is formed on either side of the collector layer, while a conductive stress application layer is formed on either side of at least the base layer. Thus, a connecting electrode can be extracted from either side of the base layer, and a tensile stress can be locally applied to the silicon post. Therefore, the carrier mobility can be improved in the base and collector layers without increasing in RB or decreasing in BVceo, and the performance (f_{T} characteristics) of the high-speed bipolar transistor can greatly be improved.

The vertical high-speed bipolar transistor of the second embodiment can be applied to both an NPN structure and a PNP structure. However, when it is applied to an NPN structure, the hole mobility in the collector region (P type) is improved and thus a stress application layer is provided on either side of the collector region such that a compressive stress or a tensile stress is applied to either side of the collector region in the vertical direction of the substrate.

### THIRD EMBODIMENT

FIG. 17 shows a configuration of a semiconductor device according to a third embodiment of the present invention. In the third embodiment, the semiconductor device will be described taking a vertical high-withstanding low-resistance field-effect transistor. The same components as those of the semiconductor device shown in FIGS. 1A and 1B are denoted by the same reference numerals and their detailed descriptions are omitted.

In the third embodiment, an epitaxial substrate 41 having an N⁺ buried layer 40 is used in place of the silicon substrate 11. Specifically, a plate-shaped (or bar-shaped) silicon substrate 41a including an N⁺ buried layer 40 is formed as a semiconductor layer on the major surface of the epitaxial substrate 41. An N⁻ drain layer (N type drift layer) 42 is formed in advance on the silicon post 41a.

A stress application layer 21 is formed on either side of at least each of the N⁺ buried layer 40 and the N⁻ drain layer 42 of the silicon post 41a to apply a tensile stress to either side in the vertical direction. As the stress application layer 21, for example, an insulative SiN film (nitride film) or a laminated film of a SiN film and a SiO₂ film is used.

An insulation film 43 is provided on the major surface of the epitaxial substrate 41, except where the silicon post 41a and the stress application layer 21 are formed. A gate electrode 44 is provided on the insulation film 43.

A P⁻ channel region 45 is provided on the surface of the silicon post 41a as part of the gate electrode 44. An N⁺ source layer 46 is formed in part of the surface area of the P⁻ channel region 45.

A source electrode 48 is provided on the gate electrode 44 with a gate insulation film 47 therebetween. The source electrode 48 is partly connected to the N⁺ source layer 46.

With the vertical high-withstanding low-resistance field-effect transistor so configured, the carriers (electrons) injected into the N⁻ drain layer 42 can be improved in mobility in the layer 42. More specifically, the transistor can be improved in performance (increased in withstanding voltage and decreased in resistance) and its N-type drift layer (N⁻ drain layer 42) can be decreased in resistance without lowering the withstanding voltage.

An example of a method of manufacturing the vertical high-withstanding low-resistance field-effect transistor shown in FIG. 17 will be described in brief. In the third embodiment, a very common process is used in the example of the manufacturing method and, for example, the order of steps is not limited to the process.

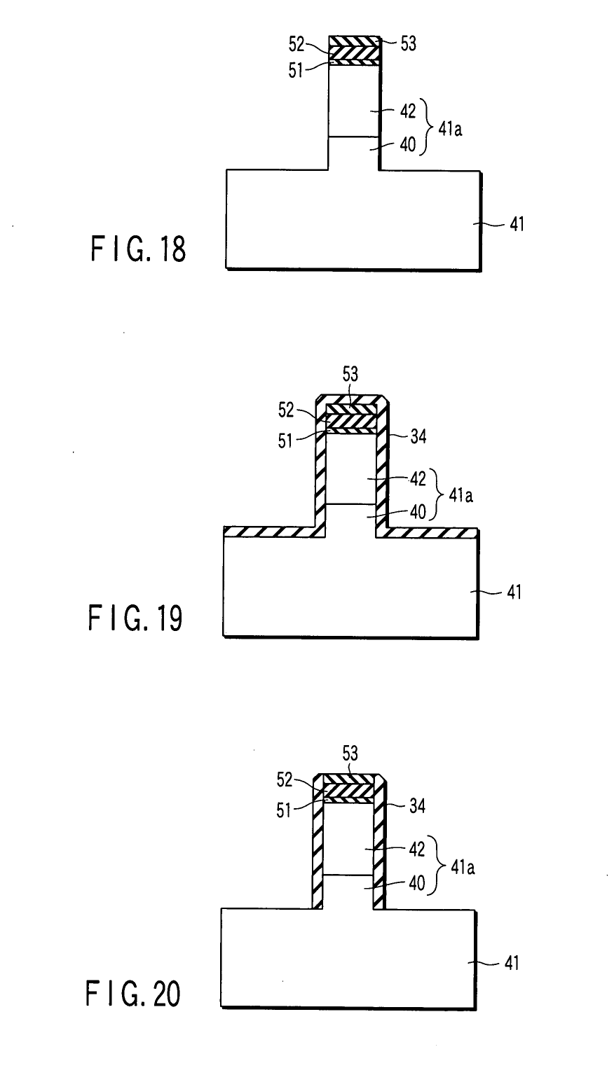

Referring first to FIG. 18, an N⁺ buried layer is formed in the major surface area of an epitaxial substrate 41 and then an epitaxial layer serving as an N⁻ drain layer 42 is grown by epitaxial growth. An insulation film 51, a nitride film 52, and an insulation film 53 are formed in sequence on the epitaxial layer by CVD. Then, the insulation film 53, nitride film 52 and insulation film 51 are removed by selective RIE, except where a silicon post 41a is formed. After that, the epitaxial layer and the major surface area of the epitaxial substrate 41 (N⁺ buried layer 40) are removed by selective RIE, except where the silicon post 41a is formed. Thus, the silicon post 41a is shaped like a plate (or a bar) on the major surface of the epitaxial substrate 41 and includes the N⁺ buried layer 40 and N⁻ drain layer 42.

After that, the resist (not shown) used for forming the silicon post 41a is eliminated and, as shown in FIG. 19, a nitride film 34, which is to serve as a stress application layer 21, is formed by CVD in the major surface area of the epitaxial substrate 41 including an outer region of the silicon post 41a.

Referring then to FIG. 20, the nitride film 34 is removed by selective RIE from the major surface of the epitaxial substrate 41 and from the insulation film 53. Thus, the major surface of the epitaxial substrate 41 and the top surface of the insulation film 53 are exposed.

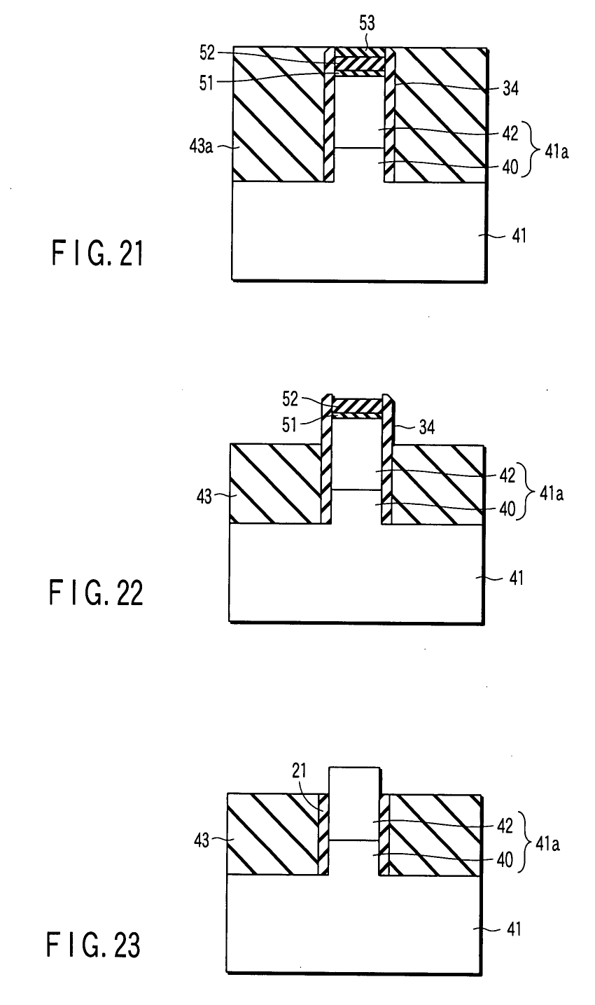

Referring then to FIG. 21, an insulation film 43a is formed by CVD at least on the major surface of the epitaxial substrate 41. Then, the top surface of the insulation film 43a is flattened by CMP such that it is flush with the top surface of the insulation film 53.

Referring then to FIG. 22, the top surface of the insulation film 43a and the insulation film 53 are removed by etching. Then, the etching is performed such that the top surface of the insulation film 43a becomes lower than that of the N⁻ drain layer 42, thereby completing the insulation film 43.

Referring then to FIG. 23, the nitride film 34 that protrudes from the top surface of the insulation film 43 is removed by etching, and the nitride film 52 and insulation film 51 are removed. Thus, the stress application layer 21 made of the nitride film 34 is completed.

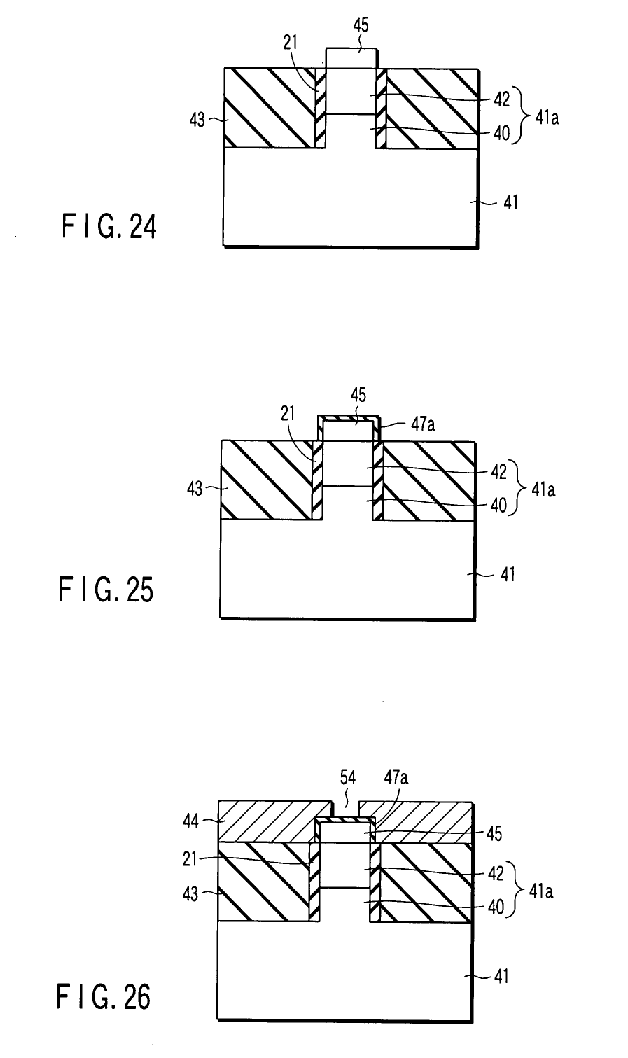

Referring then to FIG. 24, P-type impurities such as boron (B) are ion-implanted and RTA is performed to form a p⁻ channel region 45 on the silicon post 41a that is exposed to the top surfaces of the insulation film 43 and stress application layer 21.

Referring then to FIG. 25, an insulation film 47a which is to serve as a gate insulation film 47 is formed in the surface area of the p⁻ channel region 45.

Referring then to FIG. 26, a polysilicon film containing p-type impurities, which is to serve as a gate electrode 44, is formed by CVD on the entire surface of the resultant structure. After that, the polysilicon film is removed by selective etching from a portion where an N⁺ source layer 46 is formed, thus forming an opening 54 that reaches the insulation film 47a.

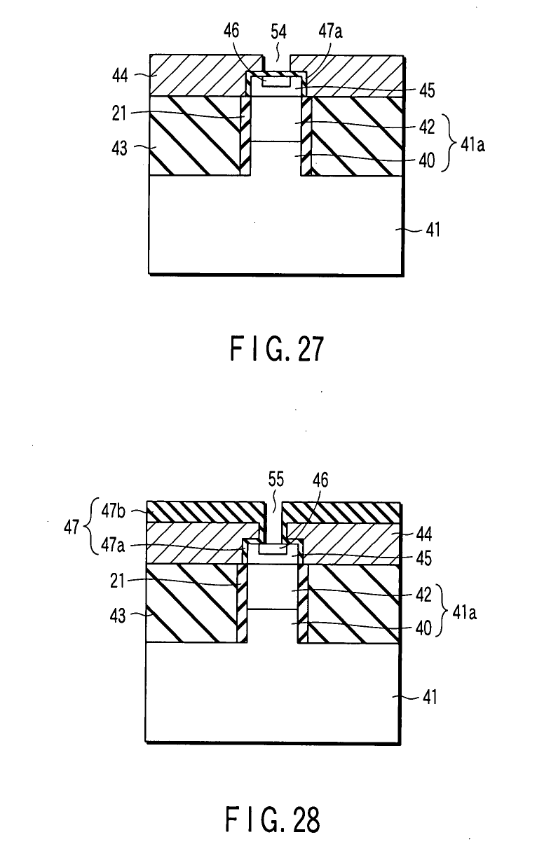

Referring then to FIG. 27, impurities are implanted into the opening 54 through the insulation film 47 to complete the N⁺ source layer 46 in the surface area of the P⁻ channel region 45.

Referring then to FIG. 28, an insulation film 47b, which is to serve as a gate insulation film 47, is formed by CVD on the entire surface of the resultant structure. After that, the insulation films 47a and 47b are removed by selective etching to forming an opening 55 that reaches the N⁺ source layer 46.

Finally, a source electrode 48 is formed by PVD on the gate insulation film 47 and in the opening 55 to complete the vertical high-withstanding low-resistance field-effect transistor with the structure shown in FIG. 17.

As described above, a stress application layer for applying a tensile stress to either side of the plate-shaped or bar-shaped silicon post in the vertical direction of the epitaxial substrate having an N⁺ buried layer, is provided on the major surface of the epitaxial substrate. In the vertical high-withstanding low-resistance field-effect transistor including an N⁻ drain layer, a P⁻ channel region and an N⁺ source layer in the vertical direction, an insulative stress application layer is formed on either side of the N⁻ drain layer. Thus, a tensile stress can be locally applied to the drain layer. Therefore, the carrier mobility can be improved in the N⁻ drain layer and the N-type drift layer (N⁻ drain layer) can be decreased in resistance without lowering a withstanding voltage.

The vertical high-withstanding low-resistance field-effect transistor of the third embodiment can be applied to a P-channel type as well as an N-type. However, when it is applied to a P-channel type, the hole mobility in the P⁻ drain layer is improved and thus a stress application layer is provided on either side of the P⁻ drain layer such that a compressive stress or a tensile stress is applied to either side of the P⁻ drain layer in the vertical direction of the substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate having a semiconductor layer on a major surface thereof, the semiconductor layer being formed to extend in a vertical direction of the major surface; and
a stress application layer provided on either side of the semiconductor layer, the stress application layer applying a stress to the semiconductor layer.

2. The semiconductor device according to claim 1, wherein the semiconductor layer is shaped like one of a plate and a bar.

3. The semiconductor device according to claim 1, wherein the stress application layer applies a distortion stress locally to the semiconductor layer.

4. The semiconductor device according to claim 3, wherein the distortion stress is a tensile stress that is exerted in the vertical direction of the semiconductor layer.

5. The semiconductor device according to claim 1, wherein the stress application layer is insulative.

6. The semiconductor device according to claim 1, wherein the stress application layer is conductive.

7. The semiconductor device according to claim 1, wherein the semiconductor substrate and the stress application layer compose a vertical transistor.

8. The semiconductor device according to claim 7, wherein the vertical transistor is a high-speed bipolar transistor.

9. The semiconductor device according to claim 7, wherein the vertical transistor is a high-withstanding low-resistance field-effect transistor.

10. A semiconductor device comprising:
a semiconductor substrate having a semiconductor layer on a major surface thereof, the semiconductor layer being formed to extend in a vertical direction of the major surface;
a collector layer and a base layer both formed in the semiconductor layer;
a first stress application layer formed on either side of the collector layer of the semiconductor layer to apply a stress to the collector layer;
a second stress application layer formed on either side of the base layer of the semiconductor layer to apply a stress to the base layer;
a base electrode connected to the base layer;
an emitter layer provided on the semiconductor layer; and
an emitter electrode connected to the emitter layer.

11. The semiconductor device according to claim 10, wherein the semiconductor layer is shaped like one of a plate and a bar.

12. The semiconductor device according to claim 10, wherein the first stress application layer and the second stress application layer apply a distortion stress locally to the semiconductor layer.

13. The semiconductor device according to claim 12, wherein the distortion stress is a tensile stress that is exerted in a vertical direction of the semiconductor layer.

14. The semiconductor device according to claim 10, wherein the first stress application layer is insulative, and the stress application layer is conductive.

15. A semiconductor device comprising:
a semiconductor substrate having a semiconductor layer on a major surface thereof, the semiconductor layer being formed to extend in a vertical direction of the major surface;
a drain layer formed in the semiconductor layer;
a stress application layer provided on either side of the drain layer of the semiconductor layer, the stress application layer applying a stress to the drain layer;
a channel region provided on the semiconductor layer;
a gate electrode provided close to the channel region;
a source layer provided in the channel region; and
a source electrode connected to the source layer.

16. The semiconductor device according to claim 15, wherein the semiconductor layer is shaped like one of a plate and a bar.

17. The semiconductor device according to claim 15, wherein the stress application layer applies a distortion stress locally to the semiconductor layer.

18. The semiconductor device according to claim 17, wherein the distortion stress is a tensile stress that is exerted in a vertical direction of the semiconductor layer.

19. The semiconductor device according to claim 15, wherein the stress application layer is insulative.

20. The semiconductor device according to claim 15, wherein the semiconductor layer includes a buried layer.
